(19) United States
(12) Patent Application Publication
(10) Pub. No.: US 2026/0231460 A1
(43) Pub. Date: Aug. 6, 2026

(54) STRUCTURES INCLUDING A HIGH-ELECTRON-MOBILITY TRANSISTOR AND RELATED METHODS

(71) Applicant: GlobalFoundries U.S. Inc., Malta, NY (US)

(72) Inventors: Richard Rassel, Essex Junction, VT (US); Zhong-Xiang He, Essex Junction, VT (US); Gary Milo, Milton, VT (US); Brett Cucci, Colchester, VT (US); Andre Sturm, Essex Junction, VT (US)

(21) Appl. No.: 19/045,840

(22) Filed: Feb. 5, 2025

(51) Int. Cl. H10D 30/47; H10D 62/85; H10D 62/852; H10D 64/01; H10D 84/01; H10D 84/86

(52) U.S. Cl. CPC H10D 30/475; H10D 64/01; H10D 84/0123; H10D 84/86; H10D 62/8503; H10D 62/852

(57) ABSTRACT

Structures for a high-electron-mobility transistor and methods of forming such structures. The structure comprises a dielectric layer including an opening and a recess adjacent to the first opening. The opening extends fully through the dielectric layer, and the recess extends partially through the dielectric layer. The structure further comprises a device structure including a gate that has a portion inside the opening.

### STATEMENT REGARDING FEDERALLY SPONSORED RESEARCH OR DEVELOPMENT

This invention was made with government support under HQ0727790700 awarded by the Defense Microelectronics Activity. The government has certain rights in the invention.

### BACKGROUND

The disclosure relates to semiconductor device fabrication and integrated circuits and, more specifically, to structures including a high-electron-mobility transistor and methods of forming such structures.

Compound semiconductors are characterized by advantageous material properties, such as a carrier mobility that is higher than the carrier mobility of silicon and a wider band gap than silicon, that can be exploited to fabricate device structures. Compound semiconductors may include, for example, Group III elements (e.g., aluminum, gallium, and/or indium) and Group V elements (e.g., nitrogen, phosphorus, arsenic, and/or antimony) combined with the Group III elements.

High-electron-mobility transistors based on compound semiconductors can be deployed in certain integrated circuit applications, such as high-voltage power electronics. A high-electron-mobility transistor may include a heterojunction between crystalline compound semiconductor materials having different band gaps, such as a heterojunction between binary gallium nitride and trinary aluminum-gallium nitride. During operation, a high concentration of high-mobility electrons accumulates near the heterojunction to supply a two-dimensional electron gas.

A conventional high-electron-mobility transistor is characterized by multiple terminals, namely a metal gate, a source ohmic contact, and a drain ohmic contact. The metal gate is used to control electron flow within the two-dimensional electron gas between the source ohmic contact and the drain ohmic contact. Chip designs require an extremely low pattern density at the metal gate level. Typically, only a few metal gates with extremely narrow width are used in each chip. The low pattern density presents a significant challenge to conventional metal etching equipment utilized to fabricate high-electron-mobility transistors. Consequences of the low pattern density include an inability to adequately control the critical dimension and an inability to adequately control corrosion.

Improved structures including a high-electron-mobility transistor and methods of forming such structures are needed.

### SUMMARY

In an embodiment of the invention, a structure comprises a dielectric layer including an opening and a recess adjacent to the first opening. The opening extends fully through the dielectric layer, and the recess extends partially through the dielectric layer. The structure further comprises a device structure including a gate that has a portion inside the opening.

In an embodiment of the invention, a method comprises forming a plurality of gates and a plurality of sacrificial elements interleaved with the plurality of gates. The method further comprises removing the plurality of sacrificial elements. The plurality of gates and the plurality of sacrificial elements have a first pattern density. The plurality of gates have a second pattern density.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 is a cross-sectional view of a structure at an initial fabrication stage of a processing method in accordance with embodiments of the invention.

FIG. 2 is a cross-sectional view of the structure at a fabrication stage subsequent to FIG. 1.

FIG. 3 is a cross-sectional view of the structure at a fabrication stage subsequent to FIG. 2.

FIG. 4 is a cross-sectional view of the structure at a fabrication stage subsequent to FIG. 3.

FIG. 5 is a cross-sectional view of a structure in accordance with alternative embodiments.

### DETAILED DESCRIPTION

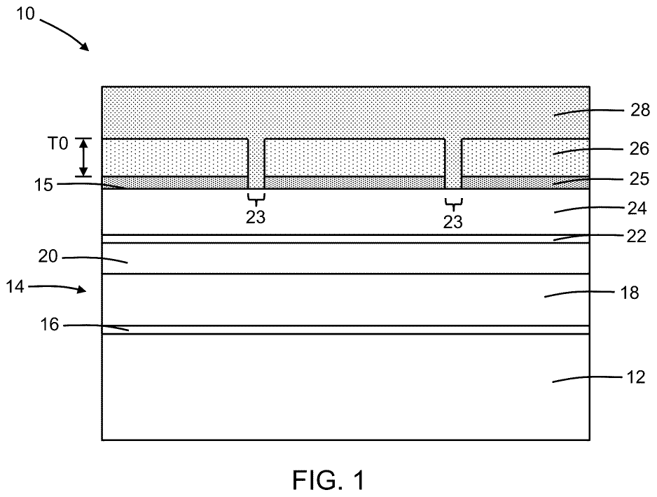

With reference to FIG. 1 and in accordance with embodiments of the invention, a structure 10 may include a layer stack 14 that is formed on a top surface of a substrate 12. The substrate 12 may be comprised of a single-crystal semiconductor material, such as single-crystal silicon. In an embodiment, the substrate 12 may be a bulk substrate that contains a single-crystal semiconductor material, such as single-crystal silicon. In an embodiment, the single-crystal semiconductor material of the substrate 12 may have a diamond crystal lattice structure with a <111> crystal orientation. The substrate 12 may be doped to have, for example, p-type conductivity. In alternative embodiments, the substrate 12 may be a different type of substrate, such as a sapphire substrate, an engineered substrate, a silicon-on-insulator substrate, a silicon carbide substrate, etc.

The layer stack 14 may include a seed layer 16, a buffer layer 18, a channel layer 20, a spacer layer 22, and a barrier layer 24 each comprised of one or more compound semiconductor materials. The layers 16, 18, 20, 22, 24 may be serially formed using an epitaxial growth process to form the layer stack 14. Each of the layers 16, 18, 20, 22, 24 of the layer stack 14 may have a crystal structure that is single crystal or, alternatively, a crystal structure that is substantially single crystal with varying levels of crystalline defectivity present. The layer stack 14 may have a thickness, for example, on the order of five (5) micrometers.

The seed layer 16, which provides a thin nucleation layer for the growth of the buffer layer 18, may be comprised of, for example, aluminum nitride. The buffer layer 18 may be comprised of one or more binary or ternary III-V compound semiconductor materials, such as aluminum gallium nitride, gallium nitride, aluminum nitride, or a layered combination of these materials. The buffer layer 18 is tailored in terms of material composition, doping, layering, and/or layer thickness to accommodate lattice mismatch, thermal property differences, and mechanical property differences between the material of the substrate 12 and the material of the channel layer 20. The channel layer 20, which is positioned between the buffer layer 18 and the spacer layer 22, may be comprised of a binary III-V compound semiconductor material, such as gallium nitride. The channel layer 20 may include a sublayer comprised of undoped gallium nitride adjacent to the spacer layer 22 and a sublayer comprised of doped gallium nitride adjacent to the buffer layer 18. The spacer layer 22, which is positioned between the channel layer 20 and the barrier layer 24, may be comprised of a binary III-V compound semiconductor material, such as aluminum nitride. The material of the spacer layer 22 may be characterized by a higher electrical resistivity than either the material of the channel layer 20 or the material of the barrier layer 24. The barrier layer 24, which is positioned on the spacer layer 22, may contain a ternary III-V compound semiconductor, such as aluminum gallium nitride.

Dielectric layers 25, 26 may be formed on the barrier layer 24. The dielectric layer 25 may be comprised of a dielectric material, and the dielectric layer 26, which may be thicker than the dielectric layer 25, may also be comprised of a dielectric material. In an embodiment, each of the dielectric layers 25, 26 may be comprised of an oxide, such as silicon dioxide. In an alternative embodiment, the dielectric layer 25 may be comprised of a nitride, such as silicon nitride, and the dielectric layer 26 may be comprised of an oxide, such as silicon dioxide. The dielectric layer 26 may have a thickness T0. The dielectric layers 25, 26 may be patterned to form openings 23 that have a spaced-apart arrangement. In an embodiment, the openings 23 in the dielectric layers 25, 26 may extend fully through the respective thicknesses of the dielectric layers 25, 26 to the top surface 15 of the layer stack 14.

A layer 28 may be formed on the dielectric layer 26. Portions of the layer 28 may fill the openings 23 extending through the dielectric layers 25, 26, and other portions of the layer 28 may overlap with the dielectric layer 26. In an embodiment, the layer 28 may be comprised of nickel, titanium, or a combination of metals such as a combination of nickel and aluminum.

In alternative embodiments, the layer stack 14 may be omitted and the dielectric layers 25, 26 may be formed directly on the substrate 12. The layer 28 may be formed with portions that are arranged in the openings 23 in the dielectric layers 25, 26, which extend to a top surface of the substrate 12.

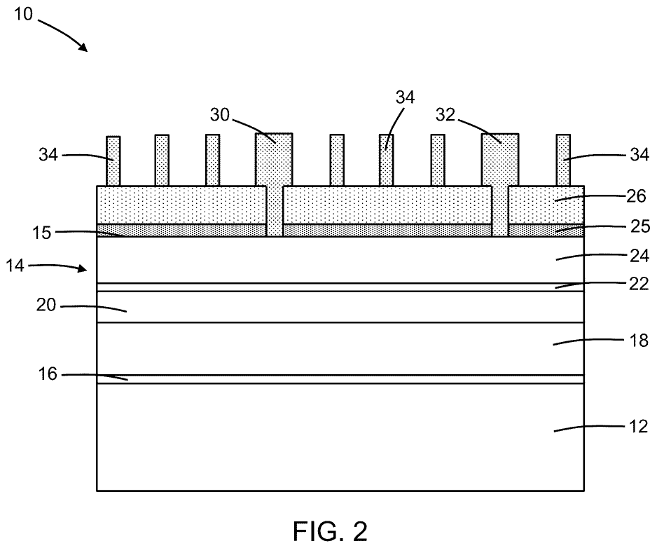

With reference to FIG. 2 in which like reference numerals refer to like features in FIG. 1 and at a subsequent fabrication stage, the layer 28 (FIG. 1) may be patterned by lithography and etching processes to define upper portions of a gate 30 and a gate 32, as well as groups of sacrificial elements 34 that are interleaved with the upper portions of the gates 30, 32. To that end, an etch mask may be formed by a lithography process over the layer 28. The etch mask may include a layer of a light-sensitive material, such as a photoresist, applied by a spin-coating process, pre-baked, exposed to light projected through a photomask, baked after exposure, and developed with a chemical developer to define resist shapes on the layer 28. An etching process, such as a reactive ion etching process, may be used to form the upper portions of the gates 30, 32 and the sacrificial elements 34 at the locations of the resist shapes. The etching process may fully remove the layer 28 over areas that are not masked by the etch mask. The etch mask may be stripped by, for example, ashing after forming the upper portions of the gates 30, 32 and the sacrificial elements 34.

In an embodiment, the upper portions of the gates 30, 32 and the sacrificial elements 34 may have different cross-sectional areas from a top-down perspective. In an embodiment, the upper portions of the gates 30, 32 and the sacrificial elements 34 may have equal thicknesses. In an embodiment, the upper portions of the gates 30, 32 and the sacrificial elements 34 may have different cross-sectional areas from a top-down perspective and equal thicknesses. The upper portions of the gates 30, 32 and the sacrificial elements 34 may provide respective contributions to a comparatively high pattern density of etched features. For example, the pattern density may range from thirty percent (30%) to seventy percent (70%). Pattern density may be represented by the ratio of the raised area including the upper portions of the gates 30, 32 and the sacrificial elements 34 to the total area of a region encompassing the upper portions of the gates 30, 32 and the sacrificial elements 34. The sacrificial elements 34 are subsequently removed and therefore are absent in the completed high-electron-mobility transistors.

Each of the gates 30, 32 may be associated with a device structure, such as a high-electron-mobility transistor. The gate 30 includes a lower portion inside one of the openings 23 in the dielectric layers 25, 26 and an adjoined upper portion that is patterned along with the sacrificial elements 34. The gate 32 includes a lower portion inside one of the openings 23 in the dielectric layers 25, 26 and an adjoined upper portion that is patterned along with the sacrificial elements 34. The upper portions of the gates 30, 32 define gate heads and the lower portions of the gates 30, 32 define gate stems with a height determined by the thickness of the dielectric layers 25, 26.

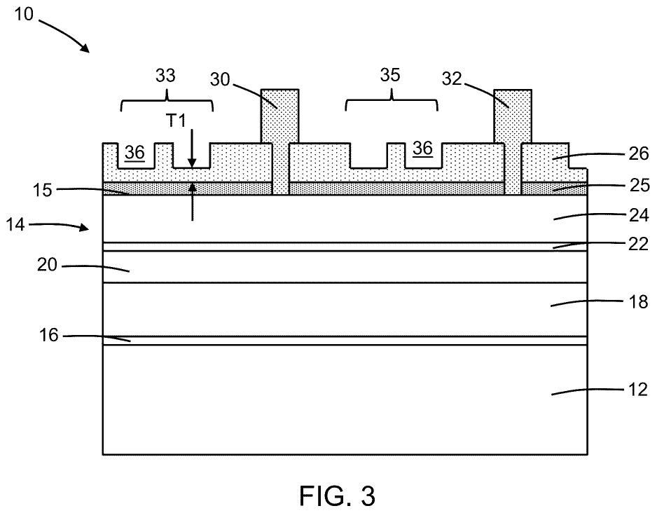

With reference to FIG. 3 in which like reference numerals refer to like features in FIG. 2 and at a subsequent fabrication stage, the sacrificial elements 34 (FIG. 2) may be etched and removed selective to the upper portions of the gates 30, 32 by lithography and etching processes. To that end, an etch mask may be formed by a lithography process that includes a layer of a light-sensitive material, such as a photoresist, applied by a spin-coating process, pre-baked, exposed to light projected through a photomask, baked after exposure, and developed with a chemical developer to define resist shapes that cover the upper portions of the gates 30, 32 and nearby portions of the dielectric layer 26. The etching process, which may be a reactive ion etching process, is used to fully remove the sacrificial elements 34 from the dielectric layer 26. The etch mask may be stripped by, for example, ashing after removing the sacrificial elements 34.

After removing the sacrificial elements 34, the upper portions of the gates 30, 32 remain with a comparatively low pattern density that is less than the initial comparatively-high pattern density that existed after patterning the layer 28. For example, the pattern density after removing the sacrificial elements 34 may be less than or equal to about one percent (1%).

The dielectric layer 26 may include recesses 36 formed by the etching process at locations that are not covered by either the etch mask or the sacrificial elements 34. The recesses 36 extend through only a portion of the dielectric layer 26 such that the recesses 36 extend partially through the dielectric layer 26. The dielectric layer 26 may have a thickness T1 at the locations of the recesses 36 that is less than the original thickness T0. The dielectric layer 26 includes steps at the edges of the recesses 36 at which the thickness transitions from the thickness T1 to the larger thickness T0.

The recesses 36 may be arranged in a group 33 and a group 35, and the recesses 36 in the different groups 33, 35 are interleaved with the gates 30, 32. The group 35 of the recesses 36 is arranged in a lateral direction between the lower and upper portions of the gate 30 and the lower and upper portions of the gate 32 in the dielectric layer 26. The lower and upper portions of the gate 30 are arranged in a lateral direction between the group 33 of the recesses 36 and the group 35 of the recesses 36. In the group 35 of the recesses 36 between the lower and upper portions of the gate 30 and the lower and upper portions of the gate 32, one of the recesses 36 is arranged in a lateral direction between another of the recesses 36 and the lower and upper portions of the gate 30, and one of the recesses 36 is arranged in a lateral direction between another of the recesses 36 and the lower and upper portions of the gate 32. The lower and upper portions of the gate 30 are arranged in a lateral direction between the recesses 36 in the group 33 and the recesses 36 in the group 35.

In an embodiment, the number of recesses 36 in each of the groups 33, 35, as well as the related number of sacrificial elements 34 that result in the formation of the recesses 36, may be greater than the number in the representative embodiment. The recesses 36 in the group 33 may be arranged in a lateral direction between the lower and upper portions of the gate 30 and the lower and upper portions of another gate (not shown). The lower and upper portions of the gate 32 may be arranged in a lateral direction between the recesses 36 in the group 35 and another group of recesses (not shown).

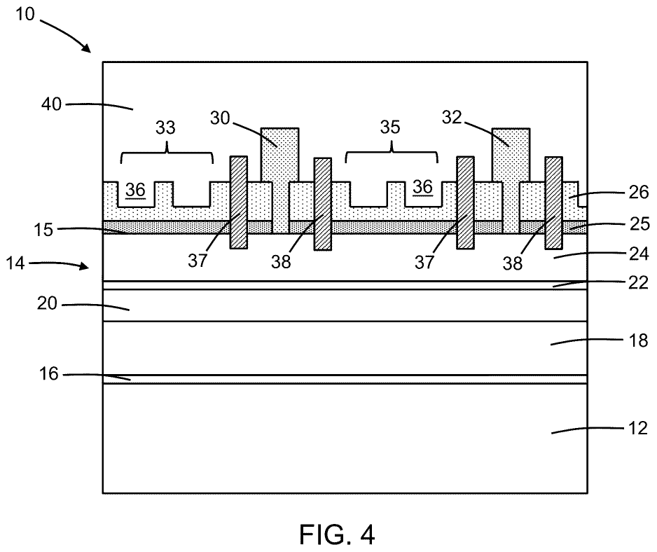

With reference to FIG. 4 in which like reference numerals refer to like features in FIG. 3 and at a subsequent fabrication stage, an ohmic contact 37 and an ohmic contact 38 may be formed that are positioned adjacent to each of the gates 30, 32. The lower and upper portions of the gate 30 are positioned in a lateral direction between one of the ohmic contacts 37 and one of the ohmic contacts 38, and the lower and upper portions of the gate 32 are also positioned in a lateral direction between one of the ohmic contacts 37 and one of the ohmic contacts 38. In an embodiment, the ohmic contacts 37 and the ohmic contacts 38 are located in respective openings that extend fully through the dielectric layers 25, 26 and that extend partially through the barrier layer 24. The ohmic contacts 37 and the ohmic contacts 38 may contain a mixture of polycrystalline grains that are comprised of aluminum, titanium, and silicon and polycrystalline grains that are comprised of aluminum. The ohmic contacts 37, 38 may be formed in portions of the dielectric layer 26 having the thickness T0.

The ohmic contacts 37, 38 are arranged in a lateral direction between the recesses 36 and the lower and upper portions of the gate 30. The group 35 of the recesses 36 is arranged in a lateral direction between the ohmic contact 38 adjacent to the lower and upper portions of the gate 30 and the ohmic contact 37 adjacent to the lower and upper portions of the gate 32. The lower and upper portions of the gate 30, the adjacent ohmic contact 37, and the adjacent ohmic contact 38 are arranged in a lateral direction between the group 33 of the recesses 36 and the group 35 of the recesses 36. In the group 35 of the recesses 36 between the lower and upper portions of the gate 30 and the lower and upper portions of the gate 32, one of the recesses 36 is arranged in a lateral direction between another of the recesses 36 and the ohmic contact 38 adjacent to the lower and upper portions of the gate 30, and one of the recesses 36 is arranged in a lateral direction between another of the recesses 36 and the ohmic contact 37 adjacent to the lower and upper portions of the gate 32.

In an embodiment, the ohmic contacts 37 and the ohmic contacts 38 may represent respective terminals of device structures, such as respective terminals of high-electron-mobility transistors. In an embodiment, the ohmic contacts 37 may represent source terminals of the high-electron-mobility transistors and the ohmic contacts 38 may represent drain terminals of the high-electron-mobility transistors. The gates 30, 32 also represent terminals of the high-electron-mobility transistors.

A dielectric layer 40 may be formed that overlies the gates 30, 32 and the ohmic contacts 37, 38. Portions of the dielectric layer 40 may fill the recesses 36. In an embodiment, portions of the dielectric layer 40 may fully fill the recesses 36. The dielectric layer 40 may be comprised of a dielectric material. In an embodiment, each of the dielectric layer 40 may be comprised of an oxide, such as silicon dioxide. In an embodiment, the dielectric layer 26 and the dielectric layer 40 may be comprised of the same dielectric material. In an embodiment, the dielectric layer 26 and the dielectric layer 40 may be comprised of different dielectric materials.

Embodiments of the invention provide a two-mask solution for low-pattern-density metal plasma etching when forming the widely-spaced gates 30, 32 of high-electron-mobility transistors. The gates 30, 32 and the sacrificial elements 34 are formed in a pattern having a comparatively high pattern density. The high pattern density tightens control over the critical dimension of the upper portions of the gates 30, 32 overlying the dielectric layer 26 and may function to reduce corrosion. The removal and elimination of the sacrificial elements 34 reduces the pattern density of the gates 30, 32, prior to the formation of the ohmic contacts 37 and the ohmic contacts 38.

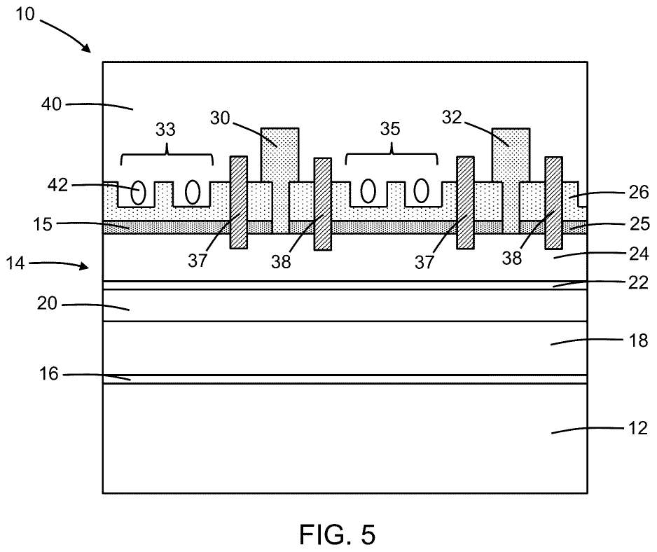

With reference to FIG. 5 and in accordance with alternative embodiments, the recesses 36 in the dielectric layer 26 may include air gaps 42 embedded within the portions of the dielectric layer 40 inside the recesses 36. The air gaps 42, which represent sealed cavities formed during the deposition of the dielectric layer 40, are unfilled by solid dielectric material and are instead filled by a gas. The gas-filled air gaps 42 may be characterized by a permittivity or dielectric constant of near unity (i.e., vacuum permittivity), which is less than the permittivity of the dielectric material of the dielectric layer 40. The air gaps 42 may be filled by atmospheric air at or near atmospheric pressure, may be filled by another gas at or near atmospheric pressure, or may contain atmospheric air or another gas at a sub-atmospheric pressure (e.g., a partial vacuum).

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value or precise condition as specified. In embodiments, language of approximation may indicate a range of +/−10% of the stated value(s) or the stated condition(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction or plane in the frame of reference perpendicular to the horizontal plane, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or “directly contacting” another feature if intervening features are absent. A feature may be “indirectly on” or in “indirect contact” with another feature if at least one intervening feature is present. Different features may “overlap” if a feature extends over, and covers a part of, another feature. A feature may “overlie” another feature if a feature is positioned “over” another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a first dielectric layer including a first opening and a first recess adjacent to the first opening, the first opening extending fully through the first dielectric layer, and the first recess extending partially through the first dielectric layer; and
a first device structure including a first gate, the first gate having a portion inside the first opening.

2. The structure of claim 1 wherein the first dielectric layer includes a second opening, the second opening extends fully through the first dielectric layer, the first device structure includes a first ohmic contact inside the second opening, and the first ohmic contact is arranged in a lateral direction between the first recess and the portion of the first gate.

3. The structure of claim 2 wherein the first dielectric layer includes a second recess, the second recess extends partially through the first dielectric layer, and the second recess is arranged in the lateral direction between the first recess and the first ohmic contact.

4. The structure of claim 2 wherein the first dielectric layer includes a second recess and a third opening, the second recess extends partially through the first dielectric layer, the third opening extends fully through the first dielectric layer, the first device structure includes a second ohmic contact inside the third opening, and the second ohmic contact is arranged in the lateral direction between the second recess and the portion of the first gate.

5. The structure of claim 1 wherein the first dielectric layer includes a second opening, the second opening extends fully through the first dielectric layer, and further comprising:
a second device structure including a second gate, the second gate having a portion inside the second opening,
wherein the first recess is arranged in a lateral direction between the portion of the first gate and the portion of the second gate.

6. The structure of claim 1 wherein the first dielectric layer includes a second recess, the second recess extends partially through the first dielectric layer, and the first recess is arranged in a lateral direction between the portion of the first gate and the second recess.

7. The structure of claim 6 wherein the first dielectric layer includes a third recess, the third recess extends partially through the first dielectric layer, and the portion of the first gate is arranged in the lateral direction between the third recess and the first recess.

8. The structure of claim 7 wherein the first dielectric layer includes a fourth recess, the fourth recess extends partially through the first dielectric layer, and the fourth recess is arranged in the lateral direction between the portion of the first gate and the third recess.

9. The structure of claim 1 further comprising:
a substrate; and
a layer stack on the substrate, the layer stack including a top surface and a plurality of III-V compound semiconductor layers,
wherein the first dielectric layer is positioned on the top surface of the layer stack.

10. The structure of claim 1 wherein the first dielectric layer has a first thickness at a location of the first opening and a second thickness at the location of the first recess, and the second thickness is less than the first thickness.

11. The structure of claim 10 wherein the first dielectric layer includes a step at a transition from the first thickness to the second thickness.

12. The structure of claim 1 further comprising:
a second dielectric layer on the first dielectric layer and the first device structure, the second dielectric layer including a portion inside the first recess, and the portion of the second dielectric layer including an air gap.

13. The structure of claim 1 wherein the first gate comprises a metal, and the first device structure is a high-electron mobility transistor.

14. A method comprising:
forming a plurality of gates and a plurality of sacrificial elements, wherein the plurality of gates and the plurality of sacrificial elements have a first pattern density; and
removing the plurality of sacrificial elements, wherein the plurality of gates have a second pattern density.

15. The method of claim 14 wherein the second pattern density is less than the first pattern density.

16. The method of claim 14 wherein forming the plurality of gates and the plurality of sacrificial elements comprises:
forming a plurality of openings in a dielectric layer;
depositing a layer that includes a plurality of portions in the plurality of openings; and
patterning the layer to form the plurality of gates and the plurality of sacrificial elements.

17. The method of claim 16 wherein removing the plurality of sacrificial elements comprises:
forming an etch mask covering the plurality of gates; and
removing the plurality of sacrificial elements with an etching process.

18. The method of claim 17 wherein the etching process forms a plurality of recesses in the dielectric layer between adjacent pairs of the plurality of gates.

19. The method of claim 14 further comprising:
forming a layer stack on a substrate,
wherein the layer stack includes a plurality of III-V compound semiconductor layers, and the plurality of gates and the plurality of sacrificial elements are formed on the layer stack.

20. The method of claim 19 further comprising:
forming a plurality of ohmic contacts coupled to the layer stack after removing the plurality of sacrificial elements.
